(19) United States
(12) Patent Application Publication
(10) Pub. No.: US 2023/0344410 A1
(43) Pub. Date: Oct. 26, 2023

(54) ACOUSTIC WAVE DEVICE WITH PASSIVATION LAYERS

(71) Applicant: Skyworks Solutions, Inc., Irvine, CA (US)

(72) Inventors: Rei Goto, Osaka-Shi (JP); Hironori Fukuhara, Ibaraki-Shi (JP)

(21) Appl. No.: 18/189,749

(22) Filed: Mar. 24, 2023

Related U.S. Application Data
(60) Provisional application No. 63/362,256, filed on Mar. 31, 2022.
(60) Provisional application No. 63/362,247, filed on Mar. 31, 2022.

(51) Int. Cl. H03H 9/02; H03H 9/145

(52) U.S. Cl. CPC H03H 9/145; H03H 9/02559

(57) ABSTRACT

An acoustic wave device is disclosed, the acoustic wave device can include a piezoelectric layer, an interdigital transducer electrode over the piezoelectric layer, and a multilayer passivation structure over the interdigital transducer electrode. The multilayer passivation structure has a thickness thinner than a thickness of the interdigital transducer electrode.

### INCORPORATION BY REFERENCE TO ANY PRIORITY APPLICATIONS

Any and all applications for which a foreign or domestic priority claim is identified in the Application Data Sheet as filed with the present application, including U.S. Provisional Pat. Application No. 63/362,256, filed Mar. 31, 2022, titled “ACOUSTIC WAVE DEVICE WITH PASSIVATION LAYERS,” and U.S. Provisional Patent Application No. 63/362,247, filed Mar. 31, 2022, titled “MULTILAYER PIEZOELECTRIC SUBSTRATE ACOUSTIC DEVICE WITH PASSIVATION LAYERS,” are hereby incorporated by reference under 37 CFR 1.57 in their entirety.

### BACKGROUND

### Technical Field

Embodiments of this disclosure relate to acoustic wave devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In one aspect, an acoustic wave device is disclosed. The acoustic wave device can include a piezoelectric layer, an interdigital transducer electrode formed with the piezoelectric layer, and a multilayer passivation structure over the interdigital transducer electrode. The multilayer passivation structure has a thickness thinner than a thickness of the interdigital transducer electrode. The multilayer passivation structure includes a first passivation layer and a second passivation layer.

In one embodiment, the interdigital transducer electrode is disposed on the piezoelectric layer.

In one embodiment, the acoustic wave device further includes a support substrate below the piezoelectric layer and a dielectric layer positioned between the piezoelectric layer and the support substrate such that the piezoelectric layer, the support substrate, and the dielectric layer define a multilayer piezoelectric substrate.

In one embodiment, the first passivation layer includes a silicon based material. The second passivation layer can include a silicon based material different from the silicon based material of the first passivation layer. One of the first and second passivation layers can be a silicon nitride layer and the other one of the first and second passivation layers can be a silicon oxide layer. The acoustic wave device can further include a third passivation layer over the second passivation layer. The third passivation layer can be a silicon oxynitride layer.

In one embodiment, the first passivation layer is in contact with the interdigital transducer electrode and the second passivation layer is in contact with the first layer.

In one embodiment, the first passivation layer is conformally disposed over the piezoelectric layer and the interdigital transducer electrode. The second passivation layer can be conformally disposed over the first passivation layer.

In one embodiment, the piezoelectric layer is a lithium tantalate layer.

In one embodiment, the thickness of the multilayer passivation structure is less than 80 nm.

In one embodiment, the first passivation layer has a first hardness and the second passivation layer has a second hardness that is greater than the first hardness. A thickness of the first layer can be greater than a thickness of the second layer.

In one embodiment, the multilayer passivation structure is selectively disposed over the interdigital transducer electrode such that a region over a bus bar of the interdigital transducer electrode is free from the first or second passivation layer and at least a portion of an active region of the interdigital transducer electrode is covered by the first or second passivation layer.

In one embodiment, the interdigital transducer electrode has a multilayer structure.

In one aspect, an acoustic wave device is disclosed. The acoustic wave device can include a piezoelectric layer, an interdigital transducer electrode formed with the piezoelectric layer, a first passivation layer over the piezoelectric layer, and a second passivation layer over the first passivation layer. The first passivation layer has a thickness that is thinner than a thickness of the interdigital transducer electrode.

In one embodiment, the second passivation layer has a thickness that is thinner than the thickness of the interdigital transducer electrode.

In one embodiment, the acoustic wave device further includes a support substrate below the piezoelectric layer and a dielectric layer positioned between the piezoelectric layer and the support substrate such that the piezoelectric layer, the support substrate, and the dielectric layer define a multilayer piezoelectric substrate.

In one embodiment, the first passivation layer includes a first silicon based material, and the second passivation layer includes a second silicon based material different from the first silicon based material. The acoustic wave device can further include a third passivation layer over the second passivation layer. One of the first and second passivation layers can be a silicon nitride layer, the other one of the first and second passivation layers can be a silicon oxide layer, and the third passivation layer can be a silicon oxynitride layer.

In one embodiment, the first passivation layer is in contact with the interdigital transducer electrode and the second passivation layer is in contact with the first layer. The first passivation layer can be conformally disposed over the piezoelectric layer and the interdigital transducer electrode. The second passivation layer can be conformally disposed over the first passivation layer.

In one aspect, a multilayer piezoelectric substrate acoustic wave device is disclosed. The multilayer piezoelectric substrate acoustic wave device can include a multilayer piezoelectric substrate, an interdigital transducer electrode formed with the multilayer piezoelectric substrate, and a multilayer passivation structure over the interdigital transducer electrode. The multilayer passivation structure includes a first layer having a first passivation material and a second layer having a second passivation material different from the first passivation material.

In one embodiment, the interdigital transducer electrode is disposed on the piezoelectric layer.

In one embodiment, the multilayer passivation structure has a thickness thinner than a thickness of the interdigital transducer electrode.

In one embodiment, the first passivation material includes a silicon based material, and the second passivation material includes a silicon based material. One of the first and second layers can be a silicon nitride layer and the other one of the first and second layers can be a silicon oxide layer. The multilayer passivation structure can further include a third layer over the second layer. The third layer can be a silicon oxynitride layer.

In one embodiment, the first layer is in contact with the interdigital transducer electrode and the second layer is in contact with the first layer.

In one embodiment, the first layer is conformally disposed over the piezoelectric layer and the interdigital transducer electrode. The second layer can be conformally disposed over the first passivation layer.

In one embodiment, the piezoelectric layer is a lithium tantalate layer.

In one embodiment, a thickness of the multilayer passivation structure is less than 80 nm. A thickness of the first layer is greater than a thickness of the second layer.

In one embodiment, the multilayer passivation structure is selectively disposed over the interdigital transducer electrode such that a region over a bus bar of the interdigital transducer electrode is free from the first or second layer and at least a portion of an active region of the interdigital transducer electrode is covered by the first or second layer.

In one embodiment, the interdigital transducer electrode has a multilayer structure.

In one aspect, a multilayer piezoelectric substrate acoustic wave device is disclosed. The multilayer piezoelectric substrate acoustic wave device can include a multilayer piezoelectric substrate, an interdigital transducer electrode formed with the multilayer piezoelectric substrate, and a multilayer passivation structure over the interdigital transducer electrode. The multilayer passivation structure includes a first layer having a first hardness and a second layer having a second hardness greater than the first hardness.

In one embodiment, the second hardness is at least 10% greater than the first hardness.

In one embodiment, the first layer has a first thickness and the second layer has a second thickness, the second thickness is thinner than the first thickness.

In one embodiment, the multilayer piezoelectric substrate includes a support substrate, an intermediate layer, and a piezoelectric layer positioned such that the intermediate layer is disposed between the piezoelectric layer and the support substrate.

In one embodiment, the first layer includes a first silicon based material, and the second layer includes a second silicon based material different from the first silicon based material. The multilayer passivation structure further includes a third layer over the second layer. The second layer can be a silicon nitride layer, the first layer can be a silicon oxide layer, and the third layer can be a silicon oxynitride layer.

In one embodiment, the first layer is in contact with the interdigital transducer electrode and the second layer is in contact with the first layer. The first layer can be conformally disposed over the piezoelectric layer and the interdigital transducer electrode, and the second layer can be conformally disposed over the first layer.

The present disclosure relates to U.S. Pat. Application No. [Attorney Docket SKYWRKS.1291A2], titled “MULTILAYER PIEZOELECTRIC SUBSTRATE ACOUSTIC DEVICE WITH PASSIVATION LAYERS,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of an acoustic wave device according to an embodiment.

FIG. 1B is an enlarged view of a portion of the acoustic wave device of FIG. 1A.

FIG. 2A is a graph showing simulation results of effective electromechanical coupling coefficients (k²) of the acoustic wave device of FIG. 1A with different thicknesses of first and second layers of a multilayer passivation structure.

FIG. 2B is a graph showing simulation results of frequency variables of the acoustic wave device of FIG. 1A with different thicknesses of first and second layers of a multilayer passivation structure.

FIG. 3A is a schematic cross-sectional side view of an acoustic wave device according to an embodiment.

FIG. 3B is a schematic cross-sectional side view of an acoustic wave device according to another embodiment.

FIGS. 4A-4D are schematic top plan views of an IDT electrode with a passivation layer disposed thereon, according to various embodiments.

FIG. 5A is a schematic diagram of a transmit filter that includes a surface acoustic wave resonator according to an embodiment.

FIG. 5B is a schematic diagram of a receive filter that includes a surface acoustic wave resonator according to an embodiment.

FIG. 6 is a schematic diagram of a radio frequency module that includes a surface acoustic wave resonator according to an embodiment.

FIG. 7 is a schematic diagram of a radio frequency module that includes filters with surface acoustic wave resonators according to an embodiment.

FIG. 8 is a schematic block diagram of a module that includes an antenna switch and duplexers that include a surface acoustic wave resonator according to an embodiment.

FIG. 9A is a schematic block diagram of a module that includes a power amplifier, a radio frequency switch, and duplexers that include a surface acoustic wave resonator according to an embodiment.

FIG. 9B is a schematic block diagram of a module that includes filters, a radio frequency switch, and a low noise amplifier according to an embodiment.

FIG. 10A is a schematic block diagram of a wireless communication device that includes a filter with a surface acoustic wave resonator in accordance with one or more embodiments.

FIG. 10B is a schematic block diagram of another wireless communication device that includes a filter with a surface acoustic wave resonator in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, ladder filters, and multi-mode SAW (MMS) filters (e.g., double mode SAW (DMS) filters). A SAW resonator can be configured to generate, for example, a Rayleigh mode surface acoustic wave or a shear horizontal mode surface acoustic wave. Although embodiments may be discussed with reference to SAW resonators, any suitable principles and advantages disclosed herein can be implemented in any suitable SAW devices.

In general, high quality factor (Q), large effective electromechanical coupling coefficient (k²), high frequency ability, and spurious free response can be significant aspects for micro resonators to enable low-loss filters, stable oscillators, and sensitive sensors.

SAW resonators can include a multilayer piezoelectric substrate. Multi-layer piezoelectric substrates can provide good thermal dissipation characteristics and improved temperature coefficient of frequency (TCF) relative to certain single layer piezoelectric substrates. For example, certain SAW resonators with a piezoelectric layer on a high impedance layer, such as silicon, can achieve a better temperature coefficient of frequency (TCF) and thermal dissipation compared to similar devices without the high impedance layer. A better TCF can contribute to obtaining the large effective electromechanical coupling coefficient (k²). Various embodiments of SAW devices disclosed herein can have a multilayer piezoelectric substrate (MPS) structure.

A SAW device such as an MPS SAW device includes an interdigital transducer (IDT) electrode on a piezoelectric layer. The IDT electrode can be covered with a passivation layer to protect the IDT electrode. For example, the passivation layer can protect the IDT electrode against corrosion. A silicon nitride (SiN) layer can be used as the passivation layer. However, effective electromechanical coupling coefficient (k²) is degraded when the SiN layer is used as the passivation layer over the IDT electrode. Silicon dioxide (SiO₂) layer can be used as the passivation layer. However, the SiO₂ layer may not provide sufficient protection for the IDT electrode.

Various embodiments disclosed herein relate to acoustic wave devices that include a multilayer passivation structure. An acoustic wave device can be an MPS SAW device. The acoustic wave device can include a piezoelectric layer, an interdigital transducer electrode over the piezoelectric layer, and the multilayer passivation structure. The multilayer passivation layer can include two or more passivation layers. For example, the multilayer passivation layer can include at least a first layer and a second layer. The first layer and the second layer can include different materials, thicknesses, and/or hardnesses. In some embodiments, the first layer and the second layer can include silicon based materials. The first layer and the second layer can be selected from silicon nitride and silicon oxide. For example, the first or second layer can be a silicon nitride layer and the other one of the first or second layer can be a silicon oxide layer. The multilayer passivation structure can provide sufficient protection for the interdigital transducer electrode while enabling the acoustic wave device to have a relatively large effective electromechanical coupling coefficient (k²).

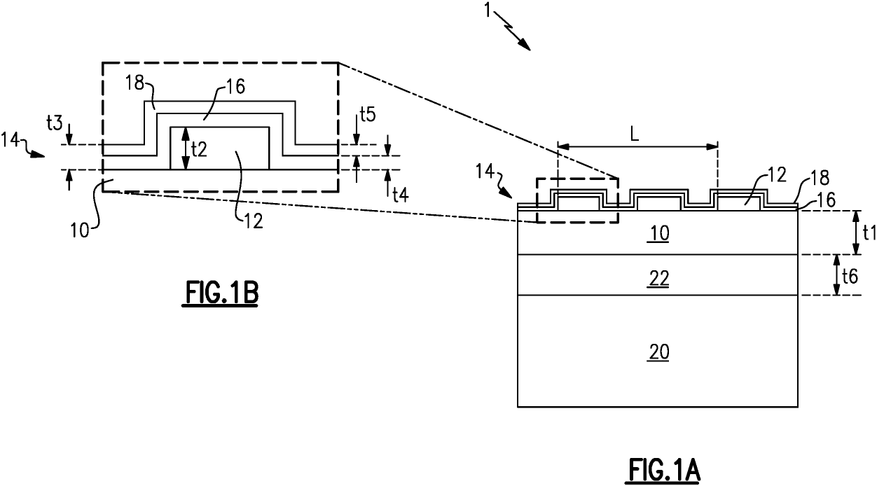

FIG. 1A is a schematic cross-sectional side view of an acoustic wave device 1 according to an embodiment. FIG. 1B is an enlarged view of a portion of the acoustic wave device 1 shown in FIG. 1A. The acoustic wave device 1 can include a piezoelectric layer 10, an interdigital transducer (IDT) electrode 12 formed with (e.g., disposed at least partially within, disposed on or over, or embedded or buried in) the piezoelectric layer 10, a multilayer passivation structure 14 over the IDT electrode 12. The multilayer passivation structure 14 can include a first layer 16 and a second layer 18. The acoustic wave device 1 can include a support substrate 20 under the piezoelectric layer 10, and an intermediate layer 22 disposed between the piezoelectric layer 10 and the support substrate 20. The piezoelectric layer 10, the support substrate 20, and the intermediate layer 22 can together define a multilayer piezoelectric substrate. The acoustic wave device 1 can be a multilayer piezoelectric substrate (MPS) surface acoustic wave (SAW) device.

The piezoelectric layer 10 can be a lithium tantalate (LT) layer. For example, the piezoelectric layer 10 can be an LT layer having a cut angle R° rotated Y-cut X propagation LiTaO3 (R°YX-LT) in a range between 20° and 60°, such as 42°. The cut angle of the piezoelectric layer 10 can be expressed in Euler angle and the cut angle can be, for example, 110° < θ < 150°. Any other suitable piezoelectric material, such as a lithium niobate (LN) layer or an aluminum nitride (AlN) layer, can be used as the piezoelectric layer 10.

The IDT electrode 12 can include any suitable IDT electrode material(s). For example, an IDT electrode 12 can include one or more of an aluminum (Al) layer, a molybdenum (Mo) layer, a tungsten (W) layer, a titanium (Ti) layer, a platinum (Pt) layer, a gold (Au) layer, a silver (Ag) layer, copper (Cu) layer, a Magnesium (Mg) layer, a ruthenium (Ru) layer, iridium (Ir), chromium (Cr) or the like. The IDT electrode 12 may include alloys, such as AlMgCu, AlCu, etc.

The first layer 16 and the second layer 18 of the multilayer passivation structure 14 can include any suitable passivation materials. For example, the passivation materials can protect the IDT electrode 12 against corrosion (e.g., oxidation). In some embodiments, the first layer 16 and/or the second layer 18 can be a trimming layer for frequency trimming. The first layer 16 and the second layer 18 can include different materials, thicknesses, and/or hardnesses. One of the first and second layers 16, 18 can provide more protective function than the other one of the first and second layers 16, 18. For example, one of the first and second layers 16, 18 can predominantly provide protective function, and the other one of the first and second layers 16, 18 can provide temperature compensative function. In some embodiments, the first layer 16 and/or the second layer 18 can include a silicon based material, such as silicon oxide (e.g., silicon dioxide (SiO₂)), silicon nitride, silicon oxinitride, or the like material, or aluminum based material, such as aluminum oxide or aluminum nitride. For example, one of the first and second layers 16, 18 can be a silicon oxide layer, such as a SiO₂ layer, and the other one of the first and second layers 16, 18 can be a silicon nitride layer.

In some embodiments, a hardness difference between the first and second layers 16, 18 can be more than 10% or more than 20%. For example, one of the first and second lays 16, 18 can have a hardness on the mohs scale of 8 or more (e.g., 8.5) and the other one of the first and second layers 16, 18 can have a hardness on the mohs scale of 7 or more (e.g., 7).

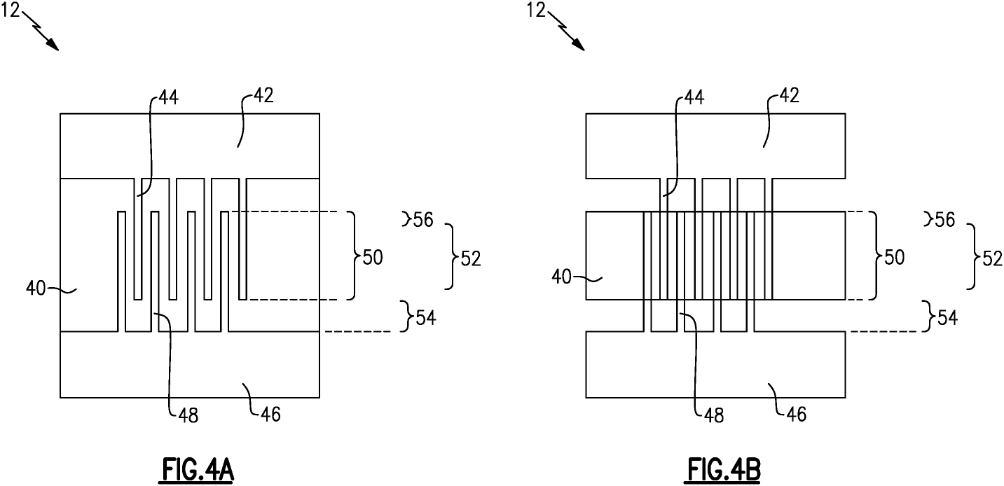

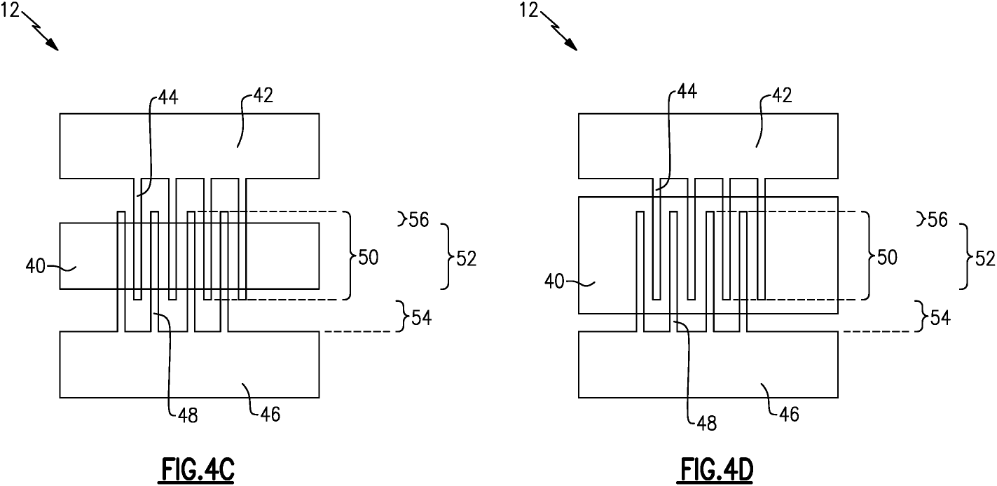

The first layer 16 can at least partially cover the IDT electrode 12 and the piezoelectric layer 10. For example, the first layer 16 can conformally cover portions of the IDT electrode 12 and the piezoelectric layer 10. The second layer 18 can at least partially cover the second layer 18. For example, the second layer 18 can condormally cover portions of the first layer 16. As described below with respect to FIGS. 4B-4D, the first layer 16 and/or the second layer 18 can be selectively disposed over portions of the IDT electrode 12. In some embodiments, the first layer 16 and/or the second layer 18 can be provided by way of deposition (e.g., sputter deposition).

In some embodiments, the support substrate 20 and/or the intermediate layer 22 can act as a heat dissipation layer. The support substrate 20 can be a silicon substrate, a quartz substrate, a sapphire substrate, a polycrystalline spinel (e.g., Mg₂O₄ spinel) substrate, a ceramic substrate, a diamond substrate, a diamond like carbon substrate, aluminum nitrite substrate, or any other suitable carrier substrate. In some embodiments, the intermediate layer 22 can act as an adhesive layer. The intermediate layer 22 can include any suitable material. The intermediate layer 22 can be, for example, an oxide layer, such as a silicon dioxide (SiO₂) layer, a doped fluorine (F) layer, such as SiO₂ doped F layer, or a titanium layer.

The multilayer piezoelectric substrate can include additional layer(s). In some embodiments, the acoustic wave device 1 can also include a trap rich layer (not shown) disposed between the support substrate 20 and the intermediate layer 22. In such embodiments, the piezoelectric layer 10, the support substrate 20, the intermediate layer 22, and the trap rich layer can together define the multilayer piezoelectric substrate. The tap rich layer can include, for example, polycrystalline silicon, amorphous silicon, porous silicon, or silicon nitride. The trap rich layer can have a multilayer trap rich structure. In some embodiments, the tap rich layer may be a region at or near an interface between the support substrate 20 and the intermediate layer 22, and may not form a distinctive layer distinctive of the support substrate 20 and/or the intermediate layer 22.

The piezoelectric layer 10 has a thickness t1, the IDT electrode 12 has a thickness t2, the multilayer passivation structure 14 has a thickness t3, the first layer 16 has a thickness t4, the second layer 18 has a thickness t5, and the intermediate layer 22 has a thickness t6.

In some embodiments, the thickness t1 of the piezoelectric layer 10 can be in a range between 0.1 L and 0.3 L. In some embodiments, the thickness t2 of the IDT electrode 12 can be in a range between 0.02L and 0.15 L, such as, in a range between 0.03 L and 0.15 L, 0.05 L and 0.15 L, 0.075 L and 0.15 L, 0.02 L and 0.125 L, 0.02 L and 0.1 L, 0.05 L and 0.125 L, or 0.05L and 0.1 L. In some embodiments, the thickness t6 of the intermediate layer 22 can be in a range between 0.1 L and 0.3L.

In some embodiments, the thickness t3 of the multilayer passivation structure 14 can be thinner than the thickness t2 of the IDT electrode 12. For example, the thickness t3 of the multilayer passivation structure 14 can be in a range between 10 nm to 100 nm, 20 nm to 100 nm, or 30 nm to 80 nm. In some embodiments, the thickness t4 of the first layer 16 and/or the thickness t5 of the second layer 18 can be thinner than the thickness t2 of the IDT electrode 12. For example, the thickness t4 of the first layer 16 and/or the thickness t5 of the second layer 18 can be in a range between 1 nm and 50 nm, 10 nm and 40 nm, or 20 nm to 30 nm. In some embodiments, the first layer 16 and/or the second layer 18 along a side wall of the IDT electrode and along an upper surface of the IDT electrode may have different thicknesses due to the nature of the process used to form the first layer 16 and/or the second layer 18. The thicknesses t4, t5 used herein can be the maximum thicknesses of the first layer 16 and the second layer 18.

The materials and thicknesses of the first layer 16 and the second layer 18 can be selected to so as to provide sufficient protection for the acoustic wave device 1 while maintaining a relatively large effective electromechanical coupling coefficient (k²). Accordingly, the multilayer passivation structure 14 can provide more reliable protection and/or improved device performance for the acoustic wave device 1 as compared to a single layer passivation structure. Selecting the materials and thicknesses of the first layer 16 and the second layer 18 as disclosed herein can be critical in providing such advantages.

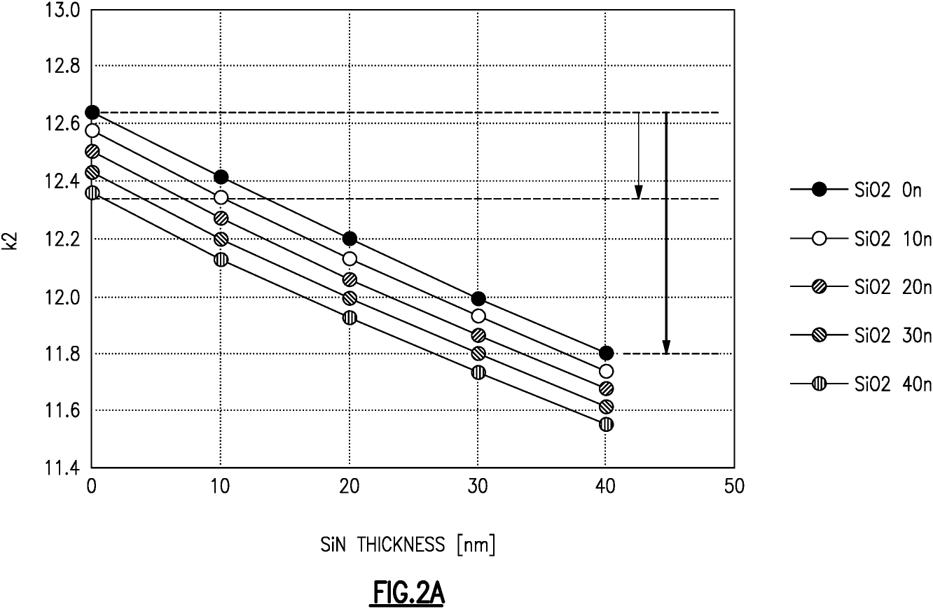

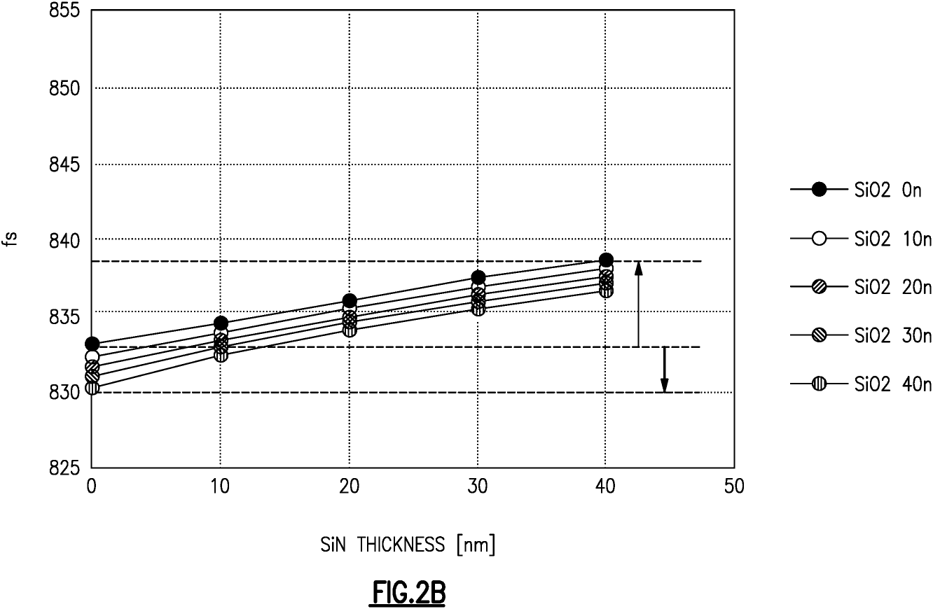

FIG. 2A is a graph showing simulation results of effective electromechanical coupling coefficients (k²) of the acoustic wave device 1 shown in FIG. 1A with different thicknesses t4, t5 of the first and second layers 16, 18. FIG. 2B is a graph showing simulation results of frequency variables of the acoustic wave device 1 shown in FIG. 1A with different thicknesses t4, t5 of the first and second layers 16, 18. In the simulations, a 42°YX LT layer with the thickness t1 of 1000 nm is used for the piezoelectric layer 10, an aluminum IDT electrode with the thickness t2 of 400 nm is used for the IDT electrode 12, a silicon dioxide SiO₂) layer is used for the first layer 16, a silicon nitride (SiN) layer is used for the second layer 18, a silicon substrate is used for the support substrate, and a SiO₂ layer with the thickness t6 of 1000 nm is used for the intermediate layer 22. A pitch of the IDT electrode 12 that can set the wavelength λ or L of the acoustic wave device 4 is set to 4.5 µm. A duty factor, which is calculated by dividing a width by L/2, of the IDT electrode 12 is set to 0.5. Various combinations of the thickness t3 of 0 nm, 10 nm, 20 nm, 30 nm, and 40 nm, and the thickness t4 of 0 nm, 10 nm, 20 nm, 30 nm, and 40 nm were used in the simulations.

The simulation results indicate that the effective electromechanical coupling coefficient (k²) is affected less by a change in the thickness t4 of the first layer 16 (the SiO₂ layer) than a change in the thickness t5 of the second layer 18 (the SiN layer). For example, as shown in FIG. 2A, 40 nm increase in the thickness t4 of the first layer 16 (the SiO₂ layer) affects the effective electromechanical coupling coefficient (k²) about 70% less than 40 nm increase in the thickness t5 of the second layer 18 (the SiN layer). Accordingly, the effective electromechanical coupling coefficient (k²) degradation may be mitigated by changing the thickness t5 of the second layer 18 (the SiN layer). For example, the multilayer passivation structure 14 enables less k² degradation with the same thickness t3 by altering the thicknesses t4, t5 of the first and second layers 16, 18.

The simulation results indicate that the sensitivity of the acoustic wave device 1 can be improved when the second layer 18 (the SiN layer) is combined with the first layer 16 (the SiO₂ layer). For example, FIG. 2B shows that the SiN frequency variable range is about two times the SiO₂ variable range. Using the multilayer passivation structure 14 can enable more flexibility in frequency trimming as compared to a single layer passivation structure.

The principles and advantages of any of the multilayer passivation structures disclosed herein can be implemented in any suitable acoustic wave devices (e.g., MPS SAW devices).

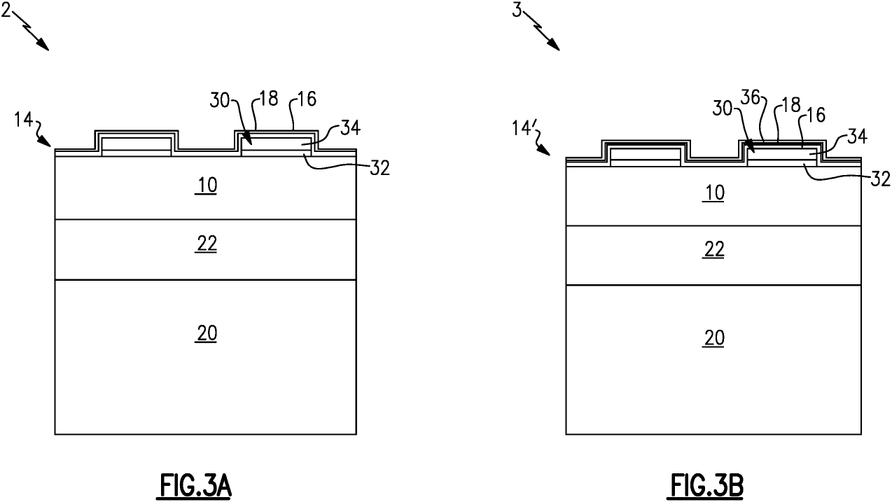

FIG. 3A is a schematic cross-sectional side view of an acoustic wave device 2. Unless otherwise noted, the components of FIG. 3A may be similar to or the same as like components disclosed herein, such as those shown in FIGS. 1A and 1B. The acoustic wave device 2 of FIG. 3A is generally similar to the acoustic wave device 1 of FIG. 1A except that an interdigital transducer (IDT) electrode 30 of the acoustic wave device 2 includes a multilayer IDT structure.

The IDT electrode 30 of the acoustic wave device 2 includes a first layer 32 and a second layer 34. The first layer 32 can be positioned on the piezoelectric layer 10 and the second layer 34 can be positioned on the first layer 32. The first layer 32 and the second layer 34 can have different densities. In some embodiments, the first layer 32 has a density that is greater than a density of the second layer 34. For example, the first layer 32 can be a molybdenum (Mo) layer and the second layer 34 can be an aluminum (Al) layer. The IDT electrode 30 can include any other suitable IDT electrode material(s). For example, the IDT electrode 30 can include one or more of an aluminum (Al) layer, a molybdenum (Mo) layer, a tungsten (W) layer, a titanium (Ti) layer, a platinum (Pt) layer, a gold (Au) layer, a silver (Ag) layer, copper (Cu) layer, a Magnesium (Mg) layer, a ruthenium (Ru) layer, or the like. The IDT electrode 30 may include alloys, such as AlMgCu, AlCu, etc. As compared to a single layer IDT electrode, multilayer IDT electrode with a layer having more dense material than the material of the single layer IDT, the multilayer IDT can be made smaller than the single layer IDT, because the same weight can be provided by a less volume with the more dense material.

The multilayer passivation structure 14 can provide sufficient protection for the acoustic wave device 2 while enabling the acoustic wave device 2 to have a relatively large effective electromechanical coupling coefficient (k²).

FIG. 3B is a schematic cross-sectional side view of an acoustic wave device 3. Unless otherwise noted, the components of FIG. 3B may be similar to or the same as like components disclosed herein, such as those shown in FIGS. 1A, 1B, and 3A. The acoustic wave device 3 of FIG. 3B is generally similar to the acoustic wave device 2 of FIG. 3A except that a multilayer passivation structure 14′ of the acoustic wave device 3 includes a third passivation layer 36.

The first layer 16, the second layer 18, and the third layer 36 of the multilayer passivation structure 14′ can include any suitable passivation materials. For example, the passivation materials can protect the IDT electrode 30 against corrosion. In some embodiments, the first layer 16, the second layer 18, and/or the third layer 36 can be a trimming layer for frequency trimming. The first layer 16, the second layer 18, and the third layer 36 can include different materials, thicknesses, and/or hardnesses. One of the first, second, third layers 16, 18, 36 can provide more protective function than the other layers. In some embodiments, the first layer 16, the second layer 18, and/or the third layer 36 can include a silicon based material, such as silicon oxide (e.g., silicon dioxide (SiO₂)), silicon nitride, silicon oxinitride, or the like material, or aluminum based material, such as aluminum oxide or aluminum nitride. For example, one of the first, second, and third layers 16, 18, 36 can be a silicon oxide layer, such as a SiO₂ layer, another one of the first, second, and third layers 16, 18, 36 can be a silicon nitride layer, and another one of the first, second, and third layers 16, 18, 36 can be a silicon oxinitride layer.

The first layer 16 can at least partially cover the IDT electrode 12 and the piezoelectric layer 10. For example, the first layer 16 can conformally cover portions of the IDT electrode 12 and the piezoelectric layer 10. The second layer 18 can at least partially cover the second layer 18. For example, the second layer 18 can condormally cover portions of the first layer 16. The third layer 36 can at least partially cover the second layer 18. For example, the third layer 36 can conformally cover portions of the second layer 18.

The multilayer passivation structure 14′ can provide sufficient protection for the acoustic wave device 3 while enabling the acoustic wave device 3 to have a relatively large effective electromechanical coupling coefficient (k²).

FIGS. 4A-4D are schematic top plan views of an IDT electrode 12 with a passivation layer 40 disposed thereon, according to various embodiments. The passivation layer 40 can be a layer (e.g., the first layer 16, the second layer 18, or the third layer 36) in a multilayer passivation structure (e.g., the multilayer passivation structure 14, 14′). As shown in FIGS. 4A-4D, at least one or more layers in the multilayer passivation structure 14, 14′ can be disposed fully or partially over the IDT electrode 12.

The IDT electrode 12 includes a first bus bar 42, first fingers 44 that extend from the first bust bar 42, a second bus bar 46, and second fingers 48 that extend from the second bus bar 46. The IDT electrode 12 can include an active region 50, center region 52 in the active region 50, a gap region 54 between the active region 50 and a bus bar (e.g., the first bus bar 42 or the second bus bar 46), and edge regions 56 at or near edges of the fingers (e.g., the first fingers 44 or the second fingers 48).

In FIG. 4A, the passivation layer 40 fully covers the IDT electrode 12. In FIG. 4B, the passivation layer 40 is disposed over the active region 50 of the IDT electrode 12. In FIG. 4C, the passivation layer 40 is disposed over the center region 52 of the IDT electrode 12. In FIG. 4D, the passivation layer 40 is disposed over the active region 50 of the IDT electrode 12 and portions of the gap regions 54. Certain passivation layer material may degrade the performance (e.g., the quality factor (Q)) of an acoustic wave device when the passivation layer 40 fully covers the IDT electrode 12 or the first and/or the second bus bar 42, 46. For example, a material such as silicon oxide (e.g., a silicon dioxide (SiO₂)) may degrade the Q when disposed over the first and/or the second bus bar 42, 46. Positions and coverages of the layers of the multilayer passivation structures disclosed herein to minimize the degradation of the performance of the acoustic wave device while providing sufficient protection for the acoustic wave device and enabling the acoustic wave device 3 to have a relatively large effective electromechanical coupling coefficient (k²).

A SAW device (e.g., an MPS SAW resonator) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS SAW resonators disclosed herein. FR1 can be from 410 MHz to 7.125 GHz, for example, as specified in a current 5G NR specification. In 5G applications, the thermal dissipation of the MPS SAW resonators disclosed herein can be advantageous. For example, such thermal dissipation can be desirable in 5G applications with a higher time-division duplexing (TDD) duty cycle compared to fourth generation (4G) Long Term Evolution (LTE). One or more MPS SAW resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

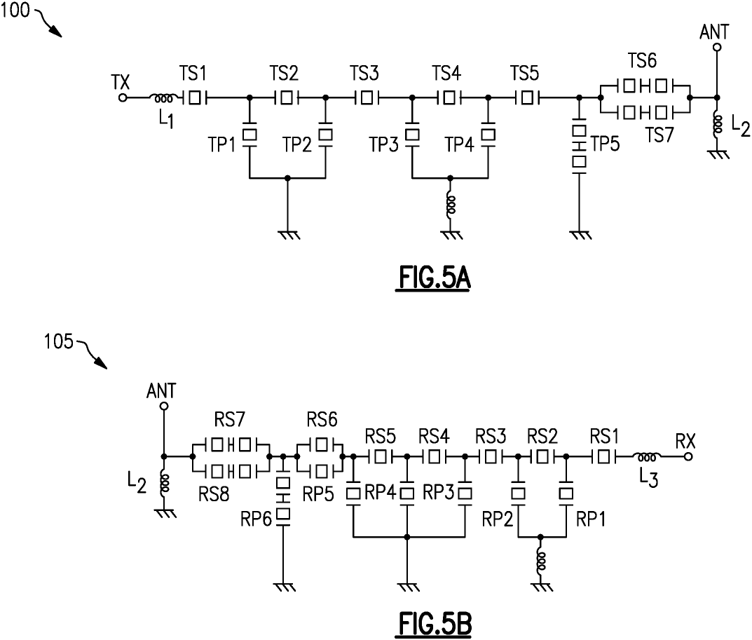

FIG. 5A is a schematic diagram of an example transmit filter 100 that includes surface acoustic wave resonators according to an embodiment. The transmit filter 100 can be a band pass filter. The illustrated transmit filter 100 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. For instance, one or more of the SAW resonators of the transmit filter 100 can be a surface acoustic wave device disclosed herein. Alternatively or additionally, one or more of the SAW resonators of the transmit filter 100 can be any surface acoustic wave resonator disclosed herein. Any suitable number of series SAW resonators and shunt SAW resonators can be included in a transmit filter 100.

FIG. 5B is a schematic diagram of a receive filter 105 that includes surface acoustic wave resonators according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators in accordance with any suitable principles and advantages disclosed herein. For instance, one or more of the SAW resonators of the receive filter 105 can be a surface acoustic wave device disclosed herein. Alternatively or additionally, one or more of the SAW resonators of the receive filter 105 can be any surface acoustic wave resonator disclosed herein. Any suitable number of series SAW resonators and shunt SAW resonators can be included in a receive filter 105.

Although some figures may illustrate example ladder filter topologies, any suitable filter topology can include a SAW resonator in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

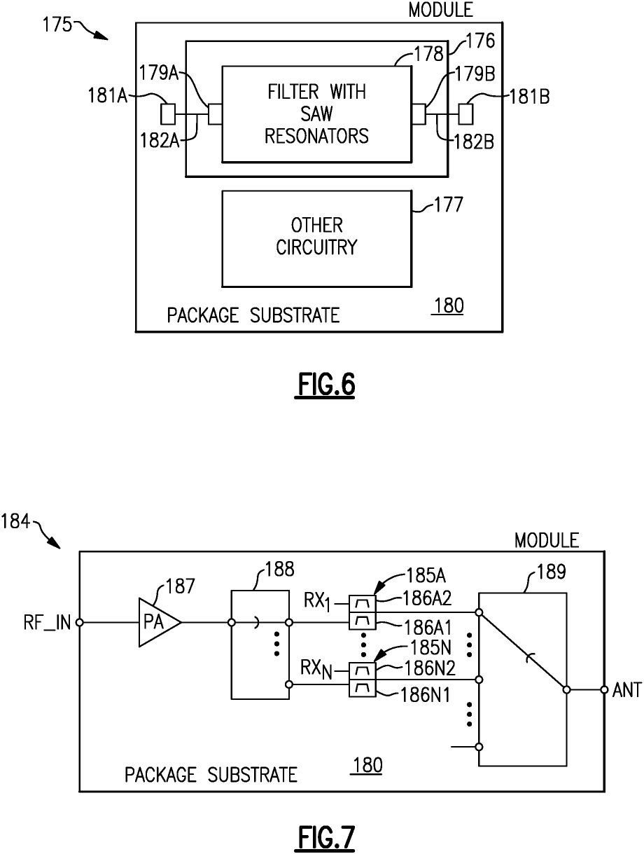

FIG. 6 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 6 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 6. The packaging substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 7 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the radio frequency module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 7 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

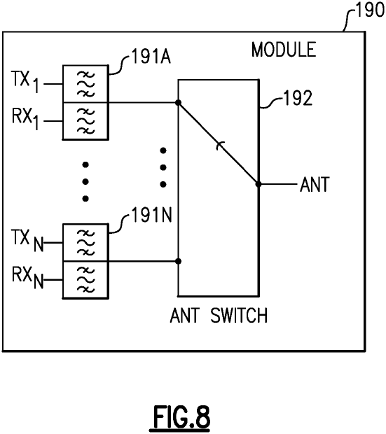

FIG. 8 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

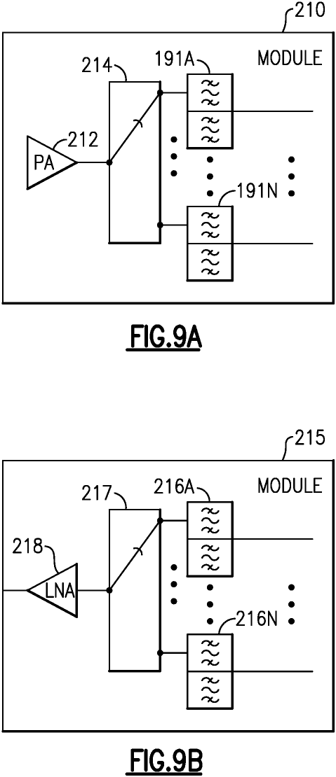

FIG. 9A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 9B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments (not illustrated), one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments (not illustrated), a plurality of low noise amplifiers can be implemented. The module 215 can include diversity receive features in certain applications.

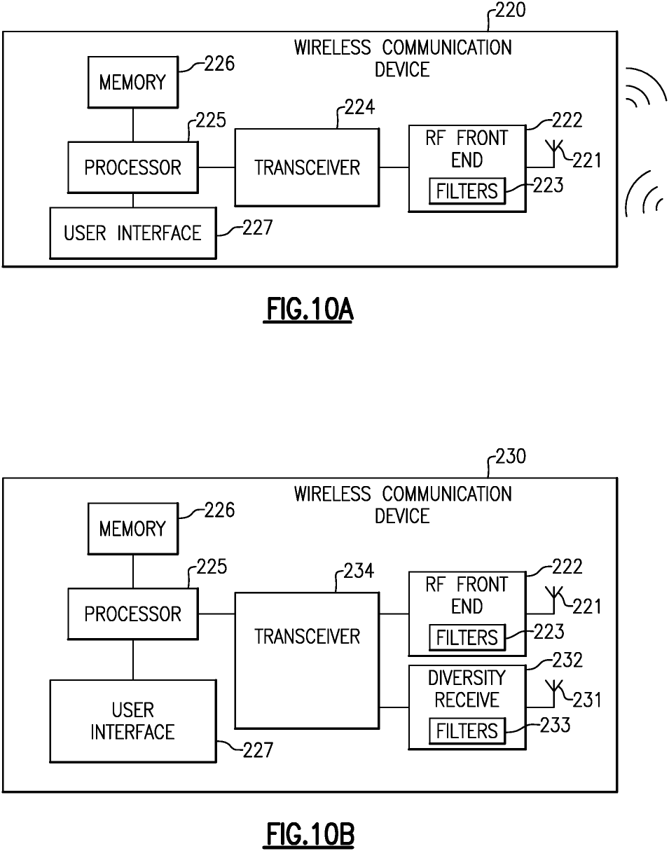

FIG. 10A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 10B is a schematic diagram of a wireless communication device 230 that includes filters 223 in a radio frequency front end 222 and a second filter 233 in a diversity receive module 232. The wireless communication device 230 is like the wireless communication device 200 of FIG. 10A, except that the wireless communication device 230 also includes diversity receive features. As illustrated in FIG. 10B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Although embodiments disclosed herein relate to surface acoustic wave resonators, any suitable principles and advantages disclosed herein can be applied to other types of acoustic wave resonators that include an IDT electrode, such as Lamb wave resonators and/or boundary wave resonators. For example, any suitable combination of features of the tilted and rotated IDT electrodes disclosed herein can be applied to a Lamb wave resonator and/or a boundary wave resonator.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a piezoelectric layer;
an interdigital transducer electrode formed with the piezoelectric layer; and
a multilayer passivation structure over the interdigital transducer electrode, the multilayer passivation structure having a thickness thinner than a thickness of the interdigital transducer electrode, the multilayer passivation structure including a first passivation layer and a second passivation layer.

2. The acoustic wave device of claim 1 wherein the interdigital transducer electrode is disposed on the piezoelectric layer.

3. The acoustic wave device of claim 1 further comprising a support substrate below the piezoelectric layer and a dielectric layer positioned between the piezoelectric layer and the support substrate such that the piezoelectric layer, the support substrate, and the dielectric layer define a multilayer piezoelectric substrate.

4. The acoustic wave device of claim 1 wherein the first passivation layer includes a silicon based material.

5. The acoustic wave device of claim 4 wherein the second passivation layer includes a silicon based material different from the silicon based material of the first passivation layer.

6. The acoustic wave device of claim 5 wherein one of the first and second passivation layers is a silicon nitride layer and the other one of the first and second passivation layers is a silicon oxide layer.

7. The acoustic wave device of claim 6 wherein the multilayer passivation structure further incldues a third passivation layer over the second passivation layer, the third passivation layer is a silicon oxynitride layer.

8. The acoustic wave device of claim 1 wherein the first passivation layer is in contact with the interdigital transducer electrode and the second passivation layer is in contact with the first layer.

9. The acoustic wave device of claim 1 wherein the first passivation layer is conformally disposed over the piezoelectric layer and the interdigital transducer electrode.

10. The acoustic wave device of claim 9 wherein the second passivation layer is conformally disposed over the first passivation layer.

11. The acoustic wave device of claim 1 wherein the piezoelectric layer is a lithium tantalate layer.

12. The acoustic wave device of claim 1 wherein the thickness of the multilayer passivation structure is less than 80 nm.

13. The acoustic wave device of claim 1 wherein the first passivation layer has a first hardness and the second passivation layer has a second hardness that is greater than the first hardness, a thickness of the first layer is greater than a thickness of the second layer.

14. The acoustic wave device of claim 1 wherein the multilayer passivation structure is selectively disposed over the interdigital transducer electrode such that a region over a bus bar of the interdigital transducer electrode is free from the first or second passivation layer and at least a portion of an active region of the interdigital transducer electrode is covered by the first or second passivation layer.

15. An acoustic wave device comprising:
a piezoelectric layer;
an interdigital transducer electrode formed with the piezoelectric layer;
a first passivation layer over the piezoelectric layer, the first passivation layer having a thickness that is thinner than a thickness of the interdigital transducer electrode; and
a second passivation layer over the first passivation layer.

16. The acoustic wave device of claim 15 wherein the second passivation layer has a thickness that is thinner than the thickness of the interdigital transducer electrode.

17. The acoustic wave device of claim 15 further comprising a support substrate below the piezoelectric layer and a dielectric layer positioned between the piezoelectric layer and the support substrate such that the piezoelectric layer, the support substrate, and the dielectric layer define a multilayer piezoelectric substrate.

18. The acoustic wave device of claim 15 wherein the first passivation layer includes a first silicon based material, and the second passivation layer includes a second silicon based material different from the first silicon based material.

19. The acoustic wave device of claim 18 further comprising a third passivation layer over the second passivation layer, wherein one of the first and second passivation layers is a silicon nitride layer, the other one of the first and second passivation layers is a silicon oxide layer, and the third passivation layer is a silicon oxynitride layer.

20. The acoustic wave device of claim 15 wherein the first passivation layer is in contact with the interdigital transducer electrode and the second passivation layer is in contact with the first layer, the first passivation layer is conformally disposed over the piezoelectric layer and the interdigital transducer electrode, and the second passivation layer is conformally disposed over the first passivation layer.
